(19) United States
(12) Patent Application Publication
(10) Pub. No.: US 2012/0248577 A1
(43) Pub. Date: Oct. 4, 2012

(54) Controlled Doping in III-V Materials

(75) Inventors: Linda T. Romano, Sunnyvale, CA (US); David P. Bour, Cupertino, CA (US); Isik C. Kizilyalli, San Francisco, CA (US); Hui Nie, Cupertino, CA (US); Thomas R. Prunty, Santa Clara, CA (US)

(73) Assignee: EPOWERSOFT INC., San Jose, CA (US)

(21) Appl. No.: 13/079,710

(22) Filed: Apr. 4, 2011

(51) Int. Cl. H01L 21/205; H01L 29/20

(52) U.S. Cl. 257/615; 438/478; 257/E21.108; 257/E29.089

(57) ABSTRACT

A method according to embodiments of the invention includes epitaxially growing a III-nitride semiconductor layer from a gas containing gallium, a gas containing nitrogen, and a gas containing indium. The concentration of indium in the III-nitride semiconductor structure is greater than zero and less than 10²⁰ cm⁻³. A structure according to embodiments of the invention includes a super lattice of alternating first and second III-nitride layers. The first layers are more highly doped than the second layers. The average dopant concentration in the super lattice is less than 10²⁰ cm⁻³.

### BACKGROUND

III-nitride materials, particularly binary, ternary, quaternary, and quinary alloys of gallium, boron, aluminum, indium, and nitrogen, have been used for years to produce semiconductor light emitting devices such as light emitting diodes and laser diodes. III-nitride materials may also have advantages for power electronics, particularly in applications requiring high voltage, high temperature operation, or high frequency operation.

III-nitride materials are often fabricated by epitaxial growth on a substrate such as sapphire, silicon, silicon carbide, or GaN. N-type layers are typically doped with Si and p-type layers are typically doped with Mg. Some epitaxial growth techniques require organic precursors, such as metal organic chemical vapor deposition (MOCVD), metal organic vapor phase epitaxy, and metal organic molecular beam epitaxy. Carbon from the organic precursors is incorporated in the III-nitride materials as a p-type background dopant.

### SUMMARY

Embodiments of the invention are directed to methods and structures for controlling the level of doping in III-nitride materials.

In embodiments of the invention, the level of doping is controlled by reducing the amount of carbon incorporated into the structure. In some embodiments, during growth of a III-nitride material, one or more substances are introduced into the reactor to reduce the amount of carbon present in the reactor, and/or to reduce the amount of carbon that is incorporated in the III-nitride material.

A method according to embodiments of the invention includes epitaxially growing a III-nitride semiconductor layer from a gas containing gallium, a gas containing nitrogen, and a gas containing indium. The concentration of indium in the III-nitride semiconductor structure is greater than zero and less than 10²⁰ cm⁻³.

In some embodiments, the level of doping is controlled with a super lattice. A structure according to embodiments of the invention includes a super lattice of alternating first and second III-nitride layers. The first layers are more highly doped than the second layers. The average dopant concentration in the super lattice is less than 10²⁰ cm⁻³.

### BRIEF DESCRIPTION OF THE DRAWINGS

FIG. 1 illustrates an example of a III-nitride doping super lattice.

FIG. 2 illustrates a high electron mobility transistor.

FIG. 3 illustrates a diode.

FIG. 4 illustrates a Schottky diode.

### DETAILED DESCRIPTION

In accordance with embodiments of the invention, techniques are described to control the doping level in III-nitride devices. Though in the examples below, the techniques are used to grow lightly doped n-type GaN doped with silicon, in other embodiments the techniques described may be used to grow more highly doped material, p-type material, material doped with dopants in addition to or other than silicon such as Ge, Se, S, O, and Te, and III-nitride materials other than GaN including but not limited to other binary III-nitride materials, ternary III-nitride materials, InGaN, AlGaN, and AlInGaN. The techniques described may be used to control doping in III-nitride materials grown on any suitable substrate including but not limited to GaN, Al₂O₃, SiC, Si, and multi-layer substrates such as silicon-on-insulator or SiC-on-insulator substrates.

Carbon incorporated into GaN during growth by a process requiring organic precursors can cause background p-type doping levels of, for example, between 10¹⁶ cm⁻³ and 10¹⁸ cm⁻³. In the case of a highly doped n-type layer (for example, doped to a concentration of 10¹⁸ cm⁻³ or higher) such as the n-type layers of a III-nitride light emitting diode, the significantly higher concentration of the n-type dopant neutralizes the effect of background carbon doping.

In some III-nitride electronic devices, it is desirable to form low doped n-type III-nitride layers or III-nitride layers that are not intentionally doped (meaning that no dopant precursor is intentionally introduced during growth). As used herein, “low doped” includes not intentionally doped layers and refers to III-nitride materials having an n-type carrier or dopant atom concentration of 10¹⁸ cm⁻³ or less in some embodiments of the invention, 10¹⁷ cm⁻³ or less in some embodiments of the invention, 10¹⁶ cm⁻³ or less in some embodiments of the invention, and between 10¹⁵ cm⁻³ and 10¹⁷ cm⁻³ in some embodiments of the invention. At low doping levels, the presence of background carbon can make the n-type dopant concentration difficult to control. In some embodiments of the invention, the doping level in a III-nitride material grown by a process requiring organic precursors is controlled by reducing the amount of carbon that is incorporated into the III-nitride material. Though the techniques below are described in the context of growing low doped n-type GaN, they may be applied to growth of any III-nitride material where reduced incorporation of carbon is desired.

The amount of carbon incorporated into GaN may be reduced by growing the GaN in the presence of a substance that inhibits carbon present in the reactor from the pyrolysis of an organic gallium precursor gas from incorporating into the nitride crystal. In some embodiments, GaN is grown in the presence of any suitable gas that includes indium such as, for example tri-methyl indium or tri-ethyl indium. Indium in the reactor during growth apparently either adheres to carbon to prevent carbon from being incorporated in the nitride crystal, or acts as a surfactant that inhibits carbon from sticking to the surface of the III-nitride material long enough to be incorporated in the crystal.

The GaN layer is grown under conditions that limit the amount of indium incorporated in the nitride crystal, such that the material is GaN doped with indium, not InGaN. The GaN layer is grown at a temperature of at least 800° C. in some embodiments, at least 900° C. in some embodiments, and at least 1000° C. in some embodiments. In some embodiments, the GaN layer is grown with a ratio of indium-containing gas to gallium precursor gas that limits the amount of indium incorporated in the nitride crystal. The ratio of indium-containing gas to gallium precursor gas may be, for example, between 1 and 80%. In some embodiments, the GaN layer is grown in the presence of hydrogen carrier gas or hydrogen mixed with nitrogen, rather than only nitrogen, particularly at lower growth temperatures such as temperatures less than 1000° C., to limit the amount of indium incorporated in the nitride crystal. A trace amount of indium is incorporated into any portion of the nitride crystal grown while the indium precursor is present in the reactor. The indium-containing portion of the nitride crystal may have a thickness on the order of tens of nanometers to tens of microns. Indium in the GaN layer may be detected by secondary ion mass spectrometry (SIMS) for example. The amount of indium incorporated in the GaN layer depends on factors such as the growth temperature, the ratio of gallium precursor gas to indium containing gas, and the growth rate, but indium concentrations of less than 10¹⁶ cm⁻³ have been observed in GaN grown in the presence of an indium containing gas. Accordingly, a GaN layer grown in the presence of an indium-containing gas may have an indium concentration less than 10²⁰ cm⁻³ in some embodiments, less than 10¹⁸ cm⁻³ in some embodiments, less than 10¹⁷ cm⁻³ in some embodiments, and less than 10¹⁶ cm⁻³ in some embodiments. In a GaN layer grown conventionally (i.e., not in the presence of an indium-containing gas), carbon may be incorporated to a concentration greater than 10¹⁷ cm⁻³. Carbon concentrations of less than 10¹⁶ cm⁻³ have been observed in GaN layers grown in the presence of tri-methyl indium. Accordingly, a GaN layer grown in the presence of an indium containing gas may have a carbon concentration less than 5×10¹⁷ cm⁻³ in some embodiments, less than 10¹⁷ cm⁻³ in some embodiments, less than 10¹⁶ cm⁻³ in some embodiments, and less than 10¹⁵ cm⁻³ in some embodiments.

The amount of carbon incorporated into GaN may also be reduced by growing the GaN from a precursor that results in less carbon being present in the reactor during growth. Since less carbon is present in the reactor, less carbon will be incorporated into the nitride crystal.

In some embodiments, a precursor that pyrolyzes in such a way that less carbon is present in the reactor during growth is used. For example, tri-ethyl gallium (TEG) may be used instead of or in addition to a typical gallium precursor such as tri-methyl gallium (TMG). GaN grown from TEG is often grown at a slower growth rate than GaN grown from TMG. Selection of the amount of TEG used during growth is a tradeoff between reduced carbon incorporation and slow growth rate. In some embodiments, low doped n-type GaN is grown with a gallium precursor that is 100% TEG or a mixture of TEG and TMG that ranges from 100% TEG to 50% TEG. Low doped n-type GaN grown with TEG as all or part of the gallium precursor may have a carbon concentration less than 10¹⁷ cm⁻³ in some embodiments, less than 10¹⁶ cm⁻³ in some embodiments, and less than 10¹⁵ cm⁻³ in some embodiments.

In some embodiments, a precursor that replaces some or all of the carbon-bearing groups with non-carbon-bearing groups, such as gallium chloride or diethyl gallium chloride, is used instead of or in addition to a typical gallium precursor such as TMG in a process requiring organic precursors, such as MOCVD. In some embodiments, low doped n-type GaN is grown with a gallium precursor that is 100% gallium chloride or diethyl gallium chloride, or a mixture of gallium chloride or diethyl gallium chloride and one or both of TEG and TMG. Low doped n-type GaN grown with gallium chloride or diethyl gallium chloride as all or part of the gallium precursor may have a carbon concentration less than 10¹⁷ cm⁻³ in some embodiments, less than 10¹⁶ cm⁻³ in some embodiments, and less than 10¹⁵ cm⁻³ in some embodiments of the invention.

The two methods described above for reducing carbon incorporation in nitride material may be combined. For example, in some embodiments, GaN is grown using both a precursor that results in less carbon present during growth, such as TEG, gallium chloride, or diethyl gallium chloride, and a material that inhibits carbon from incorporating in the nitride crystal, such as an indium-containing gas, as described above.

In general, the amount of carbon incorporated into GaN is reduced as the growth rate is reduced, because slow growth requires a higher ratio of nitrogen precursor (NH₃) to gallium precursor. The gallium precursor is the source of carbon, as described above. GaN grown at a growth rate of 1 μm/hr will have a lower carbon concentration than GaN grown at a growth rate of 5 μm/hr. For a given growth rate, less carbon may be incorporated in a GaN layer grown using one or more of the techniques described above for reducing the amount of carbon incorporated, as compared to a GaN layer grown conventionally. For example, GaN grown at a rate greater than 1 μm/hr using one or more of the techniques for reducing carbon described above may have a carbon concentration less than 10¹⁷ cm⁻³ in some embodiments, less than 10¹⁶ cm⁻³ in some embodiments, and less than 10¹⁵ cm⁻³ in some embodiments.

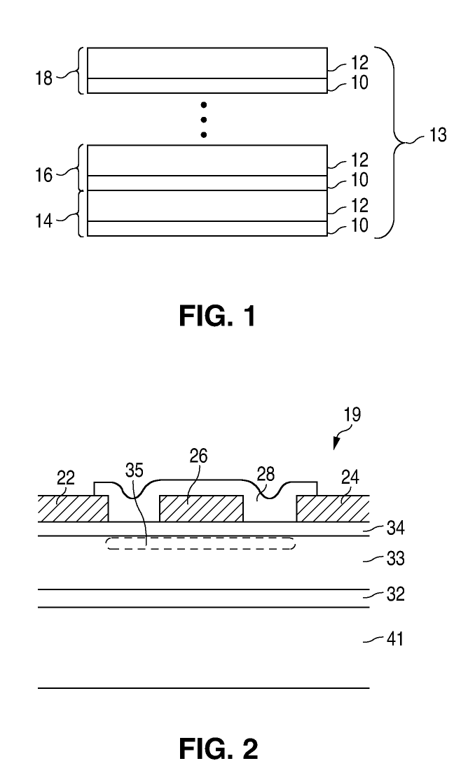

In some embodiments, the doping level in a III-nitride material is controlled by growing a doping super lattice, an example of which is illustrated in FIG. 1. Super lattice 13 includes multiple pairs 14, 16, and 18 of alternating layers 10 and 12 of different dopant concentration. More highly doped layers 10 alternate with less highly doped layers 12. The super lattice may be n-type or p-type and any suitable dopant species may be used. The dopant concentration and thickness in alternating layers 10 and 12 are selected based on the desired average dopant concentration in super lattice 13. The average dopant concentration in super lattice 13 is less than 10²⁰ cm⁻³ in some embodiments, less than 10¹⁸ cm⁻³ in some embodiments, less than 10¹⁷ cm⁻³ in some embodiments, less than 10¹⁶ cm⁻³ in some embodiments, and between 10¹⁶ cm⁻³ and 10¹⁷ cm⁻³ in some embodiments. All of the more highly doped layers 10 in the super lattice may have the same dopant concentration and thickness, though they need not. Similarly, all of the less highly doped layers 12 in the super lattice may have the same dopant concentration and thickness, though they need not.

In some embodiments, a super lattice is used to control the doping level in a low doped n-type GaN region. The dopant is typically Si but may be any suitable n-type dopant species including Ge, Se, S, O, and Te. Less highly doped layers 12 may range, for example, from not intentionally doped to a dopant concentration of 10¹⁶ cm⁻³. More highly doped layers 10 may range, for example, from a dopant concentration of 10¹⁶ cm⁻³ to 10¹⁸ cm⁻³. In one device, less highly doped layers 12 are not intentionally doped and more highly doped layers 10 are doped to a dopant concentration of 10¹⁷ cm⁻³.

In some embodiments, in particular where low n-type doping in the super lattice is desired, less highly doped layers 12 are thicker than more highly doped layers 10. Less highly doped layers 12 may be one to ten times thicker than more highly doped layers 10 in some embodiments, one to five times thicker in some embodiments, and five to ten times thicker in some embodiments. In some embodiments, more highly doped layers 10 are the same thickness or thicker than less highly doped layers 12.

Each of layers 10 and 12 may be no more than 200 nm thick in some embodiments and no more than 100 nm thick in some embodiments. Less highly doped layers 12 may be between 10 and 100 nm thick in some embodiments. More highly doped layers 10 may be between 10 and 50 nm thick in some embodiments. Super lattice 13 may include between 5 and 25 pairs of layers 10 and 12 in some embodiments. The total thickness of super lattice 13 may be between 1 and 5 microns in some embodiments.

In some embodiments, super lattice 13 may be grown using one or more of the techniques described above for reducing carbon incorporation.

FIGS. 2, 3, and 4 are three examples of devices that may be grown or may include regions grown using one or more of the techniques for controlling doping described above. The thickness of a region of a device grown using the techniques for controlling doping described above may be between 10 Å and 50 μm in some embodiments, between 10 Å and 500 Å in some embodiments, between 50 Å and 200 Å in some embodiments, and between 1 μm and 50 μm in some embodiments.

FIG. 2 illustrates a portion of a III-nitride high electron mobility transistor 19. The device includes a nucleation layer 32, such as GaN or AlGaN, grown first on a conventional substrate 41, often sapphire or SiC. A GaN region 33 is grown over nucleation layer 32. GaN region 33 may be a low doped n-type region. An AlGaN region 34 is grown over GaN region 33. Source and drain metal electrodes 22 and 24 are electrically connected to AlGaN region 34. A metal gate electrode 26 is formed on AlGaN region 34 between source and drain electrodes 22 and 24. Electrodes 22, 24, and 26 may be electrically isolated from each other by a passivation layer 28 such as a nitride of silicon or an oxide of silicon. During operation, the conductivity in the two dimensional electron gas region 35 is controlled by applying a voltage to gate electrode 26.

It is desirable to precisely control the level of doping in the low doped n-type two dimensional electron gas region 35, in order to control the electron mobility, resistance, threshold voltage, and breakdown voltage of the device. The dopant concentration in low doped n-type region 35 may be controlled using one or more of the techniques for controlling doping, as described above. For some devices, the doping level in, for example, a lower portion of GaN region 33, need not be controlled with the same precision as region 35. Accordingly, a first portion of GaN region 33 may be grown without the techniques for controlling doping described above, then a second portion of GaN region 33 including region 35 is grown using one or more of the techniques for controlling doping described above.

For example, a first portion of GaN region 33 may be n-type GaN, grown from conventional precursors. An indium-containing gas such as tri-methyl indium, a gas that reduces the amount of carbon in the reactor such as TEG, gallium chloride, or diethyl gallium chloride, or both an indium-containing gas and a gas that reduces the amount of carbon in the reactor are introduced during growth of a second portion of GaN region 33 including two dimensional electron gas region 35. In addition, the first portion may be grown at a fast growth rate and the second portion may be grown at a slower growth rate. Switching from conventional precursors to one or more gases to reduce the amount of carbon incorporated in the device may cause a step in carbon concentration at the boundary between first and second portions of GaN region 33. For example, the first portion may have a carbon concentration greater than 10¹⁷ cm⁻³ and the second portion may have a carbon concentration less than 10¹⁷ cm⁻³ in some embodiments and less than 10¹⁶ cm⁻³ in some embodiments. The concentration of carbon in the second portion of GaN region 33 including region 35 may be at least one order of magnitude less than the concentration of carbon in the first portion of GaN region 33, in some embodiments.

In another example, a first portion of region 33 is conventionally grown n-type GaN and a second portion of GaN region 33 including region 35 is an n-type GaN super lattice as described above.

In some embodiments, AlGaN layer 34 is grown using one or more of the growth techniques described above.

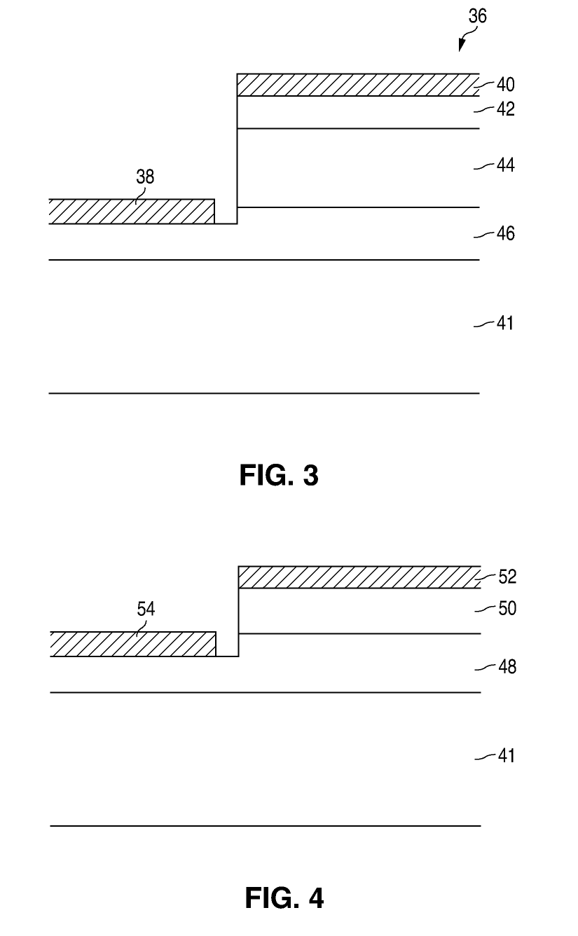

FIG. 3 illustrates a portion of a III-nitride diode. The semiconductor portion of diode 36 is grown over a substrate 41, often sapphire or SiC. A nucleation layer, not shown in FIG. 3, may be disposed between n-type region 46 and substrate 41. A low doped n-type region 44 disposed between a p-type region 42 and a highly doped n-type region 46. A metal anode 40 is formed on p-type region 42. A portion of p-type region 42 and low doped n-type region 44 are etched away to reveal a portion of highly doped n-type region 46 on which a metal cathode 38 is formed. The dopant concentration in the device, in particular in low doped n-type region 44, may be controlled using one or more of the techniques for controlling doping, as described above.

FIG. 4 illustrates a portion of a III-nitride Schottky diode. A highly doped n-type region 48 is grown over a substrate 41, often sapphire or SiC, and an optional nucleation layer. A low doped n-type region 50 is grown over n-type region 48. A portion of n-type region 50 is etched away, then metal electrodes 52 and 54 are formed on low doped n-type region 50 and highly doped n-type region 48. The dopant concentration in the device, in particular in low doped n-type region 44, may be controlled using one or more of the techniques for controlling doping, as described above.

Though a high electron mobility transistor and two diodes are illustrated above, a person of skill in the art will understand that embodiments of the invention may be used in any device where reducing carbon concentration is desired, or where controlled doping is required or desired, including but not limited to other electronic and optoelectronic devices including field effect transistors, light emitting diodes, and lasers.

Having described the invention in detail, those skilled in the art will appreciate that, given the present disclosure, modifications may be made to the invention without departing from the spirit of the inventive concept described herein. Therefore, it is not intended that the scope of the invention be limited to the specific embodiments illustrated and described.

What is being claimed is:

1. A method comprising:
epitaxially growing a III-nitride semiconductor layer from a gas containing gallium, a gas containing nitrogen, and a gas containing indium, wherein a concentration of indium in the III-nitride semiconductor layer is greater than zero and less than 10²⁰ cm⁻³.

2. The method of claim 1 wherein the III-nitride semiconductor layer is doped with an n-type dopant to an n-type dopant concentration of no more than 10¹⁷ cm⁻³.

3. The method of claim 1 wherein the III-nitride semiconductor layer is grown at a temperature of at least 1000° C.

4. The method of claim 1 wherein the III-nitride semiconductor layer is grown at a temperature of at least 800° C.

5. The method of claim 1 wherein the III-nitride semiconductor layer has a carbon concentration less than 10¹⁶ cm⁻³.

6. The method of claim 1 wherein the gas containing gallium comprises tri-ethyl gallium.

7. The method of claim 1 wherein the gas containing gallium comprises one of gallium chloride and diethyl gallium chloride.

8. The method of claim 1 wherein the III-nitride semiconductor layer is grown in the presence of hydrogen carrier gas.

9. The method of claim 1 wherein the III-nitride semiconductor layer is AlGaN.

10. The method of claim 1 wherein the III-nitride semiconductor layer has a thickness between 10 Å and 50 μm.

11. The method of claim 1 wherein the III-nitride semiconductor layer is a first III-nitride semiconductor layer, the method further comprising growing a second III-nitride semiconductor layer, wherein the second III-nitride semiconductor layer has a carbon concentration that is at least one order of magnitude greater than a carbon concentration in the first III-nitride semiconductor layer.

12. A structure comprising:
a III-nitride semiconductor layer comprising GaN and having a concentration of indium greater than zero and less than 10²⁰ cm⁻³ throughout a portion of the III-nitride semiconductor layer that is at least 10 Å thick.

13. The structure of claim 12 wherein the III-nitride semiconductor layer is doped with an n-type dopant to an n-type dopant concentration of no more than 10¹⁷ cm⁻³.

14. The structure of claim 12 wherein the III-nitride semiconductor layer has a carbon concentration less than 5×10¹⁷ cm⁻³.

15. The structure of claim 12 wherein the III-nitride semiconductor layer is a first III-nitride semiconductor layer, the structure further comprising a second III-nitride semiconductor layer, wherein the second III-nitride semiconductor layer has a carbon concentration that is at least one order of magnitude greater than a carbon concentration in the first III-nitride semiconductor layer.

16. A structure comprising:
a super lattice of alternating first and second III-nitride layers, wherein the first layers are more highly doped than the second layers and the average dopant concentration in the super lattice is less than 10²⁰ cm⁻³.

17. The structure of claim 16 wherein the second layers are thicker than the first layers.

18. The structure of claim 16 wherein:
the first layers are doped with an n-type dopant and have an n-type dopant concentration of 10¹⁶ cm⁻³ to 10¹⁸ cm⁻³; and
the second layers are not intentionally doped.

19. The structure of claim 18 wherein the n-type dopant comprises one of Si, Ge, Se, S, O, and Te.

20. The structure of claim 16 wherein the super lattice has a thickness between 1 and 5 μm.
